(19) United States
(12) Patent Application Publication
(10) Pub. No.: US 2010/0065854 A1
(43) Pub. Date: Mar. 18, 2010

(54) GROWTH AND MANUFACTURE OF REDUCED DISLOCATION DENSITY AND FREE-STANDING ALUMINUM NITRIDE FILMS BY HYDRIDE VAPOR PHASE EPITAXY

(75) Inventors: Derrick S. Kamber, Goleta, CA (US); Shuji Nakamura, Santa Barbara, CA (US); James S. Speck, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/513,326

(22) PCT Filed: Nov. 2, 2007
(86) PCT No.: PCT/US07/23209

§ 371 Date: May 1, 2009

Related U.S. Application Data
(60) Provisional application No. 60/856,181, filed on Nov. 2, 2006.

(51) Int. Cl. H01L 29/20; H01L 21/20

(52) U.S. Cl. 257/76; 438/503; 257/615; 257/E21.09; 257/E29.089

(57) ABSTRACT

A Group III-nitride semiconductor film containing aluminum, and methods for growing this film. A film is grown by patterning a substrate, and growing the Group III-nitride semi-conductor film containing aluminum on the substrate at a temperature designed to increase the mobility of aluminum atoms to increase a lateral growth rate of the Group III-nitride semiconductor film. The film optionally includes a substrate patterned with elevated stripes separated by trench regions, wherein the stripes have a height chosen to allow the Group III-nitride semiconductor film to coalesce prior to growth from the bottom of the trenches reaching the top of the stripes, the temperature being greater than 1075° C., the Group III-nitride semiconductor film being grown using hydride vapor phase epitaxy, the stripes being oriented along a (1-100) direction of the substrate or the growing film, and a dislocation density of the grown film being less than 10⁷ cm⁻².

### CROSS-REFERENCE TO RELATED APPLICATION

This application claims the benefit under 35 U.S.C. Section 119(e) of the following co-pending and commonly-assigned U.S. patent application:

U.S. Provisional Application Ser. No. 60/856,181, filed on Nov. 2, 2006, by Derrick S. Kamber, Shuji Nakamura, and James S. Speck, entitled “GROWTH AND MANUFACTURE OF REDUCED DISLOCATION DENSITY AND FREE STANDING ALUMINUM NITRIDE FILMS BY HYDRIDE VAPOR PHASE EPITAXY,” attorneys' docket number 30794.202-US-P1 (2007-163-1); which application is incorporated by reference herein.

### BACKGROUND OF THE INVENTION

1. Field of the Invention

This invention relates to the growth and manufacture of nitride-based semiconductors, and in particular to the growth and manufacture of reduced dislocation density aluminum nitride films.

2. Description of the Related Art

Al-containing III-V compound semiconductors are of significant value since they are used in the fabrication of many optoelectronic and electronic devices. Of particular interest are Al-containing III-V nitrides, also referred to as Group III-nitride, III-nitrides or III-nitride semiconductors. Generally speaking, a III-nitride semiconductor is one for which its chemical formula is (AlₓB_{y}In_{z}Ga_{1-x-y-z})N, in which 0≦x≦1, 0≦y≦1, 0≦z≦1, and 0≦x+y+z≦1. The III-nitride semiconductors, including aluminum nitride (AlN), gallium nitride (GaN), indium nitride (InN), hexagonal boron nitride (BN), and their alloys, have gained considerable interest in the past two decades due to the potential of these materials to span energy bandgaps from 0.9 eV to 6.2 eV. These alloys have direct bandgaps, making them extremely useful in optoelectronics as both detectors and emitters. Additionally, the nitrides have also been used to fabricate high-power, high-temperature and high-frequency electronic devices due to their high critical breakdown fields and superior electron transport properties. Although the present invention applies to any AlBInGaN compound containing a non-negligible amount of Al, for simplicity, the remainder of the discussion below will focus on alloys containing predominantly aluminum and gallium (AlGaN)

The addition of aluminum to III-nitrides serves to increase the bandgap of the material relative to that of pure indium nitride, pure gallium nitride, or indium gallium nitride compounds. Aluminum nitride has a large direct bandgap of 6.2 eV at room temperature, and this enables alloys containing gallium (AlGaN) to have tunable bandgaps from 3.4 eV to 6.2 eV. Changing the relative aluminum and gallium compositions in the material alters the bandgap. This control over the bandgap of the material permits device fabrication enabling emission and detection of ultraviolet (UV) and visible radiation over this entire spectral range.

Although AlGaN-based devices have been successfully fabricated, to produce improved high-power, high-frequency electronic and ultraviolet optoelectronic devices, a suitable substrate is required to enhance the performance and cost effectiveness of such devices. Currently, there are no readily available, inexpensive, high-quality substrate materials for the III-nitride semiconductors. Foreign substrates, therefore, have to be used for heteroepitaxial growth, specifically sapphire or silicon carbide, and the lattice mismatch between the growing film and the substrate leads to stress in the film and often cracking. The large lattice mismatch in heteroepitaxy (i.e. the growth of AlGaN on a foreign substrate) also typically results in a high concentration of threading dislocations (microscopic crystallographic line defects), which form at the substrate-nitride interface and generally propagate upward through the growing film. The dislocation density for MN films grown on foreign substrates is typically 10⁹ cm⁻² or higher. These defects significantly degrade device performance when they propagate into the active regions of devices.

A variety of growth techniques that utilize lateral overgrowth have been developed to reduce the dislocation density of III-nitride films, including lateral epitaxial overgrowth (LEO, ELO, or ELOG), selective area epitaxy, and PENDEO® epitaxy. These techniques have proven very successful for the growth of GaN films, some of which incorporate small fractions of either indium or aluminum. Films containing high concentrations of Al, however, have proven to be very difficult to grow by these techniques. One issue is that III-nitride alloys containing significant concentrations of Al do not demonstrate the same growth selectivity typically observed in other III-nitride films. Specifically, the oxide or nitride materials that are typically used as masking materials to prevent growth of the III-nitride films in undesired regions, the most common being silicon dioxide (SiO₂) or silicon nitride (SiₓN_{y}), does not successfully prevent the growth of Al containing III-nitride films. Instead, the Al atoms will stick to the masking material and nucleate growth. This growth is typically polycrystalline or amorphous and effectively makes lateral overgrowth of Al-containing III-nitride semiconductor films impossible by techniques that utilize a masking material for selective growth.

Another lateral growth approach is cantilever epitaxy, which is described in U.S. Pat. No. 6,599,362 B2 [1]. This method incorporates first growing a nucleation layer on a patterned substrate, then a middle layer, and finally a growth layer with a lateral growth rate approximately equal to or greater than the vertical growth rate. While this method is successful in reducing the dislocation density in the lateral growth regions to densities of 10⁷ cm⁻² or below for GaN-based alloys, it has not yet been demonstrated for III-nitride alloys containing high concentrations of Al. The slow lateral and vertical growth rates of Al-containing III-nitrides has slowed progress towards the growth of reduced defect density III-nitride films. The slow growth rates typically observed with Al-containing III-nitrides lead to extremely long growth times for film coalescence, which is undesirable for a manufacturing environment Furthermore, for the growth of III-nitride semiconductors containing high mole fractions of Al, the use of different growth process conditions as described in U.S. Pat. No. 6,599,362 B2 [1] may result in inversion domains and other undesirable features in the growing film. The growth of a single layer of Al-containing III-nitride semiconductor film on a substrate is much preferred.

Despite the difficulties present for defect reduction techniques for the growth of III-nitride alloys containing significant mole fractions of Al, two research groups have reported on LEO of AlN films. Chen et al. have demonstrated LEO of AlN films on shallow-grooved sapphire substrates using a pulsed ammonia flow MOCVD process [2]. They coalesced wing regions as wide as 4-10 μm and initially reported a reduction in the threading dislocation density in the wing regions to approximately 10⁸ cm^{-2,} as compared to the 10¹⁰ cm⁻² in the mesa/seed region. A more thorough TEM analysis, however, indicated that although the defect density was reduced in the laterally grown wing regions in the precoalescence stage, after coalescence, basal-plane threading dislocations formed at the coalescence points due to the relaxation of compressive strain that results from the temperature gradients during growth [3]. These dislocations bent toward the surface and produced laterally grown regions possessing high concentrations of edge-type threading dislocations. This means that the researchers were unable to achieve reduced threading dislocations in their AlN films.

The other research group to demonstrate AlN LEO performed MOCVD growth of AlN on patterned AlN on sapphire [4][5]. They claim to achieve dislocation densities of less than 10⁷ cm⁻² throughout the AlN film due to a combination of both lateral growth in the wing regions and also dislocation looping and annihilation in the seed regions due to the high growth temperatures. The same research group has also performed LEO of a-plane AlN on patterned a-AlN on sapphire using MOCVD growth [6]. They were able to achieve threading dislocation reduction in the laterally grown regions, but the seed regions still possessed a high dislocation density. While these results do show a reduction is dislocation density of AlN films, the characteristically slow growth rates of MOCVD prevent the rapid manufacture of AlN templates and free-standing wafers that industry demands.

It can be seen, then, that there is a need in the art for an improved method for growing nitride-based semiconductors with reduced dislocation densities.

### SUMMARY OF THE INVENTION

To overcome the limitations in the prior art described above, and to overcome other limitations that will become apparent upon reading and understanding the present invention, the present invention generally discloses a superior method for growing III-nitride semiconductor crystals containing aluminum by hydride vapor phase epitaxy (HVPE) or metalorganic chemical vapor deposition (MOCVD), along with superior low defect density Al-containing III-nitride semiconductor films.

Specifically, the present invention discloses a Group III-nitride semiconductor film containing aluminum, and methods for growing this film. A Group III-nitride film containing aluminum is grown by a method comprising patterning a substrate, and growing the Group III-nitride film containing aluminum on the patterned substrate at a temperature selected to increase the mobility of aluminum atoms to increase a lateral growth rate of the Group III-nitride film. Preferably, the temperature is greater than 1075° C.

The substrate is patterned with at least one structure from a group comprising apertures, stripes, arrays, circles, hexagons or rectangles. The structures may be oriented along a [symbol] 1-100 [symbol] direction or a [symbol] 11-20 [symbol] direction of the substrate or the Group III-nitride film.

The substrate is patterned to contain two or more elevated post regions and at least one trench region. The growth of the Group III-nitride film initiates on one or more of the elevated post regions and proceeds to grow laterally over one or more of the trench regions.

The dislocation density of the Group III-nitride film is reduced in the laterally grown regions. Preferably, the Group III-nitride film has a dislocation density of less than 10⁷ cm⁻².

The elevated post regions have a height chosen to allow the Group III-nitride film to coalesce prior to the growth from the bottom of the trench regions reaching the top of the elevated post regions, wherein the posts have a height-to-width ratio in excess of 0.5.

A nucleation, buffer, or template layer may be formed on the substrate before, during, or after the patterning step. In addition, a nucleation, buffer, or template layer my formed on the Group III-nitride film before or during the growing step. Additional layers or device structures may be grown on the Group III-nitride film.

In one embodiment, the Group III-nitride film is separated from the substrate. To accomplish this, in one embodiment, the substrate is patterned with a plurality of posts and the Group III-nitride film is separated from the substrate after cooling the substrate with the Group III-nitride film at a rate that cracks one or more of the posts, such that the Group III-nitride film is separated from the substrate by cracking of all of the posts, by applying an etchant, and/or by applying a mechanical force. In another embodiment, the substrate is patterned with a plurality of posts and the Group III-nitride film is separated from the substrate after cracking one or more of the posts on cooling from an elevated temperature due to the coefficient of thermal expansion mismatch between the Group III-nitride film and the substrate. As in the previous embodiment, a mechanical force or chemical etchant may be applied to facilitate separation of the Group III-nitride film from the substrate.

The substrate contains one or more materials from the group comprising of AlN, GaN, AlGaN, AlGaInN, sapphire (Al₂O₃), silicon carbide (SiC), silicon (Si), ZnO, GaAs, BP, GaP, spinel (MgAl₂O₄), MgO, LiGaO₂, LiAlO₂, NdGaO₃, ScAlMgO₄, Ca₈La₂(PO₄)₆O₂, MoS₂, LaAlO₃, (Mn,Zn)Fe₂O₄, Hf, Zr, ZrN, Sc, ScN, NbN, TiO₂, aluminum oxide material, TiN, a Group III-V material or a Group II-VI material.

The Group III-nitride film includes at least one of boron (B), aluminum (Al), gallium (Ga), indium (In), and thallium (Tl). The Group III-nitride film may be a semipolar or nonpolar Group III-nitride film. The Group III-nitride film may also contain one or more additional elements, including those selected from a group comprised of silicon, germanium, carbon, magnesium, beryllium, calcium, iron, cobalt, nickel, manganese, phosphorus, antimony, bismuth, and arsenic.

### BRIEF DESCRIPTION OF THE DRAWINGS

Referring now to the drawings in which like reference numbers represent corresponding parts throughout:

FIG. 1 illustrates a cross-sectional view of one embodiment of a substrate in accordance with the present invention;

FIG. 2 illustrates a Scanning Electron Microscope (SEM) photo of a prepared substrate prior to epitaxial growth in accordance with the present invention;

FIG. 3 illustrates a cross-sectional SEM image of a fully coalesced AlN film in accordance with the present invention;

FIG. 4 illustrates a tilted SEM image of a fully coalesced AlN film on a patterned substrate in accordance with the present invention;

FIG. 5 illustrates a cross-sectional Transmitting Electron Microscope (TEM) image of an AlN film grown in accordance with the present invention;

FIG. 6 illustrates a cross-sectional TEM image of an AlN film showing termination of threading dislocations at the coalescence boundary in accordance with the present invention;

FIG. 7 illustrates a plan view TEM image of an AlN film showing edge-type threading dislocations;

FIG. 8 illustrates plan view TEM images of three different 4 μm² areas in a wing region revealing no threading dislocations;

FIG. 9 illustrates a plan view TEM image of a laterally grown AlN film showing no edge-type threading dislocations;

FIG. 10. illustrates an example of cracking in the SiC substrate posts due to the coefficient of thermal expansion mismatch between the weak SiC substrate posts and the AlN layer;

FIG. 11 illustrates an example of a patterned substrate made of two different materials in accordance with the present invention;

FIG. 12 illustrates another example of a patterned substrate made of two different materials in accordance with the present invention; and

FIG. 13 is a flowchart that illustrates a method for the growth of high quality, low defect density Al-containing III-nitride semiconductor films according to a preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention has developed high quality, low defect density Al-containing III-nitride semiconductors films with dislocation densities below 10⁷ cm⁻². The films are grown via a lateral overgrowth technique by HVPE or MOCVD. Films containing reduced structural defect densities are grown on patterned substrates containing apertures or stripes where growth initiates on the raised features of the substrate and proceeds to grow laterally. Lateral growth is encouraged by growth at temperatures above 1075° C.

In another aspect of this invention, free-standing Al-containing III-nitride semiconductors film can be prepared using the lateral growth techniques described in the previous aspect of this invention. The Al-containing III-nitride semiconductor film is grown to a sufficient thickness to produce a layer with high structural integrity and mechanical stability. The free-standing layer is produced after cracking occurs in the substrate posts upon cooling after film growth due to the coefficient of thermal expansion (CTE) mismatch between the III-nitride semiconductor layer and the substrate. The CTE mismatch between the semiconductor film and the substrate results in stress in the substrate and semiconductor film upon cooling from growth temperatures to room temperature. This stress is often relieved by cracking, which according to the present invention, preferentially occurs in at least some, if not all, of the weak substrate posts during cooling. Cracking of the posts permits relatively easy separation of the Al-containing III-nitride semiconductor film from the substrate, thereby producing a free-standing Al-containing III-nitride semiconductor substrate.

Technical Description

The present invention provides a superior means of growing high-quality, low-defect density Aluminum (Al)-containing III-nitride semiconductor materials. Al-containing III-nitride semiconductors are of particular interest since they have emerged as a viable means for fabricating optoelectronic devices and high-power, high-frequency electronic devices. The growth of Al-containing nitrides has been pursued by a variety of techniques, but the unavailability of bulk crystals or lattice-matched substrates has resulted in heteroepitaxial films of poor quality possessing relatively high structural defect densities. The present invention has solved this problem by developing a lateral epitaxial growth technique that permits the fabrication of Al-containing III-nitride semiconductor films that are relatively dislocation free, with dislocation densities below 10⁷ cm⁻². Subsequent epitaxial growth on this reduced structural defect density material enables the production of improved III-nitride bulk semiconductor films and III-nitride device structures. The growth of devices on the low defect Al-containing III-nitride semiconductor material by an epitaxial device growth technique such as metalorganic chemical vapor deposition (MOCVD), molecular beam epitaxy (MBE), or hydride vapor phase epitaxy (HVPE) should significantly improve optoelectronic and electronic device performance. Furthermore, another aspect of this invention enables the production of free-standing Al-containing III-nitride semiconductor layers, and these free-standing layers may successfully be used as seed crystals for further epitaxial growth or as substrates for improved device growth.

### Defect Reduction of Al-Containing III-Nitride Semiconductor Films Via Lateral Epitaxial Overgrowth

In one aspect of this invention, we developed III-nitride semiconductor layers containing significant fractions of aluminum with reduced threading dislocation densities below 10⁷ cm⁻². The low threading dislocation density films are achieved by lateral epitaxial overgrowth using conventional metal-source hydride vapor phase epitaxy (HVPE). The films, methods, processes, and procedures described relate to the growth of all semiconductor compounds containing aluminum (Al) and nitrogen (N). The invention is particularly suitable for III-nitride semiconductor films of AlGaN or AlGaInN containing a high Al mole fraction, and even more suitable for purely AlN films. Nevertheless, the invention relates to all films that containing N and large mole fractions of Al, typically greater than 5%. Furthermore, the addition of other elements from the periodic table, for example for doping as is known within the art, is still within the scope of this invention. Examples of such elements include, but are not limited to, silicon (Si), magnesium (Mg), germanium (Ge), beryllium (Be), calcium (Ca), iron (Fe), carbon (C), cobalt (Co), manganese (Mn) and nickel (Ni). The grown materials may contain combinations of the Group III elements Al, gallium (Ga), boron (B), thallium (Tl), and indium (In), and Group V elements nitrogen (N), phosphorus (P), antimony (Sb), bismuth (Bi), and arsenic (As) in any composition and proportion. Accordingly, when the phrase “aluminum(Al)-containing III-nitride semiconductors” (or any derivates of this phrase) is used in this document, it refers to all compounds formed from elements in Groups III and V of the periodic table of the elements, that also contain aluminum (Al) and nitrogen (N). Additionally, elements not in Group III or Group V may be added to the growing film, and the addition of these elements is still within the scope of this invention. For example, a refractory metal may be added to the growing film.

The present invention also provides a means of producing Al-containing III-nitride films with reduced structural defects via lateral epitaxial overgrowth. Film growth is accomplished using conventional metal-source HVPE involving the reaction of a halide compound, such as but not limited to gaseous hydrogen chloride (HCl), with a metal source containing aluminum. The metal source may consist of pure aluminum or it may consist of a mixture of elements that includes aluminum, for example gallium and aluminum, or aluminum and magnesium. The source material may contain aluminum in any composition or proportion. The source material is heated to an elevated temperature, typically above 500° C., to facilitate reaction between the halide compound and the metal source to form halogenated aluminum products, principally AlCl and AlCl₃. The halogenated products of aluminum are then transported to the substrate by a carrier gas, generally nitrogen, hydrogen, helium, or argon. During the transport to the substrate, at the substrate, or in the exhaust stream, the Al-containing chloride will react with the Group V source, typically ammonia (NH₃), to form the Al-containing III-nitride semiconductor film. The term “film” will be used interchangeably herein with the terms “layer,” “material,” and “product,” which all refer to the grown Al-containing III-nitride crystalline material.

The present invention relies on two key elements:
1. The use of a suitable substrate, which may or may not have a buffer, nucleation, or template layer, that contains apertures, stripes, or other features enabling lateral growth.
2. Growth at temperatures above 1075° C. to increase the mobility of the Al atoms, and therefore, increase the lateral growth rate of the film.

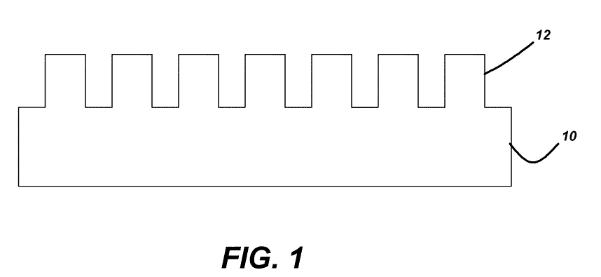

According to one aspect of this invention, the Al-containing III-nitride films are grown on patterned substrates. FIG. 1 shows an illustration of a cross-sectional view of one embodiment of a patterned substrate 10 that may be used according the present invention.

The patterned substrates 10 may be formed from any material (or materials) that permits the growth of Al-containing III-nitride semiconductor films, including but not limited to AlN, GaN, AlGaN, AlGaInN, sapphire (Al₂O₃), silicon carbide (SiC), silicon (Si), ZnO, GaAs, BP, GaP, spinel (MgAl₂O₄), MgO, LiGaO₂, LiAlO₂, NdGaO₃, ScAlMgO₄, Ca₈La₂(PO₄)₆O₂, MoS₂, LaAlO₃, (Mn,Zn)Fe₂O₄, Hf, Zr, ZrN, Sc, ScN, NbN, TiO₂ and TiN. The substrate 10 is patterned so that it contains apertures or stripes that enable lateral growth. The patterning creates one or more elevated regions 12, which are commonly referred to as mesas or posts. These mesas 12 are created so that they are able to initiate and support the epitaxial growth process. Generally, multiple elevated mesas 12 are created, along with the corresponding trenches in between the mesas 12, on the substrate 10.

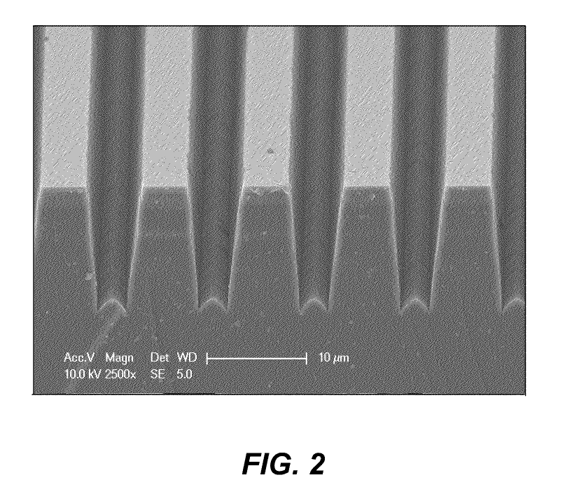

FIG. 2 is a micrograph that provides an example of a substrate prepared according to the process of the present invention. The depth of the trenches, the width of the trenches, and the width of the mesas have no significant affects on achieving successful lateral overgrowth of the Al-containing III-nitride semiconductor film. The depth of the trenches and the width of the trenches, however, are generally chosen so that film growing laterally from the mesas coalesces prior to the growth from the bottom of the trench reaching the mesa top. Furthermore, the mesas and trenches may be formed with any geometrical shape and orientation with a uniform or inconsistent spacing between mesas. The mesas and trenches may be aligned in any direction, but are generally aligned along the [symbol] 11-20 [symbol] or [symbol] 1-100 [symbol] family of crystallographic directions of the growing Al-containing III-nitride semiconductor film. The mesas may also be formed in an array.

The patterned substrates may be prepared using conventional dry or wet etching technology as is known in the art. The specific etch chemistry and technique will depend on the choice of substrate and should be chosen based on the state of the art technology for the chosen substrate. The substrates may be etched with or without a nucleation, buffer, or template layer on the substrate. Furthermore, a nucleation, buffer or template layer can be deposited on all or parts of the substrate after the etch, prior to film growth. After preparation of the substrate, the substrate is ready for growth.

Growth of the reduced defect density Al-containing III-nitride semiconductor film is achieved by HVPE. The substrate is typically placed in the growth zone of the reactor, where the growth zone refers to the region of the reactor where the reactants combine to form the III-nitride semiconductor films, generally on the substrate. Of particular importance to this invention is that the growth temperature in the growth zone of the reactor, where the patterned substrate is present, is at a temperature of 1075° C. or above. Growth at temperatures above 1075° C. increases the surface diffusion of the reactant species. The surface diffusion length (λ) is given by the expression λ=(Dτ)^{1/2}, where D is the surface diffusion coefficient and τ is the mean residence time of atoms on the surface. The surface diffusion coefficient is strongly temperature dependent, and therefore, by increasing the growth temperature the atoms are increasingly mobile on the surface of the growing film. Growth temperatures of 1075° C. or above sufficiently increase the surface diffusion to promote the lateral growth modes that are necessary to achieve significant lateral growth, and accordingly, the relatively defect-free material in these laterally grown regions.

Using the ideas, concepts, and methods of the present invention, we have demonstrated successful lateral epitaxial overgrowth (LEO) of AlN by HYPE. This is believed to be the first successful demonstration of AlN LEO by HYPE. Furthermore, we have achieved the lowest reported threading dislocation density for AlN films by any vapor phase epitaxial growth technique with a dislocation density below 10⁷ cm⁻². The AlN films were grown by conventional metal-source HVPE on patterned SiC wafers. The SiC wafers were patterned with stripes oriented along the [1-100] direction of the SiC wafer. The mesas were 2-5 μm wide and the trenches were 2-10 μm wide and 10-12 μm deep. Although these dimensions and this substrate material were used for demonstration of the invention, these demonstrations are by no means meant to limit the scope of this invention. Instead, they simply provide some examples of the successful application of the present invention for the growth of high quality AlN films. The patterned substrates were loaded into the growth zone of the HVPE reactor and the reactor was heated to temperatures above 1075° C. Once the samples had reached the desired growth temperature, growth was initiated by the flow of NH₃ and HCl. Growth occurred directly on the patterned substrate without the use of any nucleation, buffer, or template layers, although the present invention could optionally include the use of nucleation, buffer, or template layers on the patterned substrate, but in general, these layers are found to be unnecessary. Upon completion of the growth, the furnace was shut off, the flow of reactant gases was halted, and the reactor was cooled to room temperature.

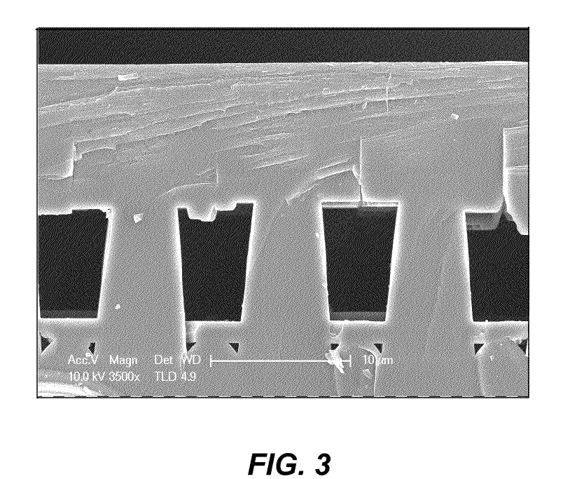

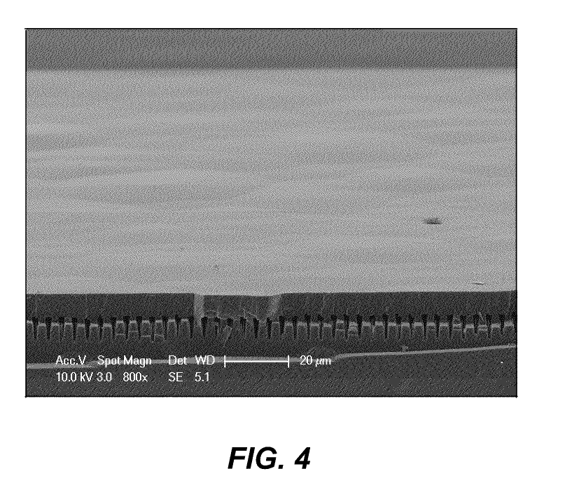

FIG. 3 and FIG. 4 show cross-sectional and tilted cross-sectional scanning electron microscopy (SEM) images, respectively, of films grown according to the present invention. These images indicate that the AlN films begin growing on top of the mesas of the patterned substrate. The films then proceed to grow laterally over the trench regions and continue to grow laterally until the AlN from two adjacent mesas coalesces, typically in the center of the trench region. After film coalescence, the films continue to grow vertically, producing AlN films possessing a smooth and uniform surface morphology, as shown in FIG. 4. Atomic Force Microscopy (AFM) imaging of the AlN films indicated that the films have a rms (root mean square) roughness of 0.71 nm over 10×10 μm² sampling areas. The sampling areas included both seed material and laterally grown wing material. This AFM imaging indicates that the surfaces of the AlN LEO films are ready for subsequent epitaxial bulk or device growth.

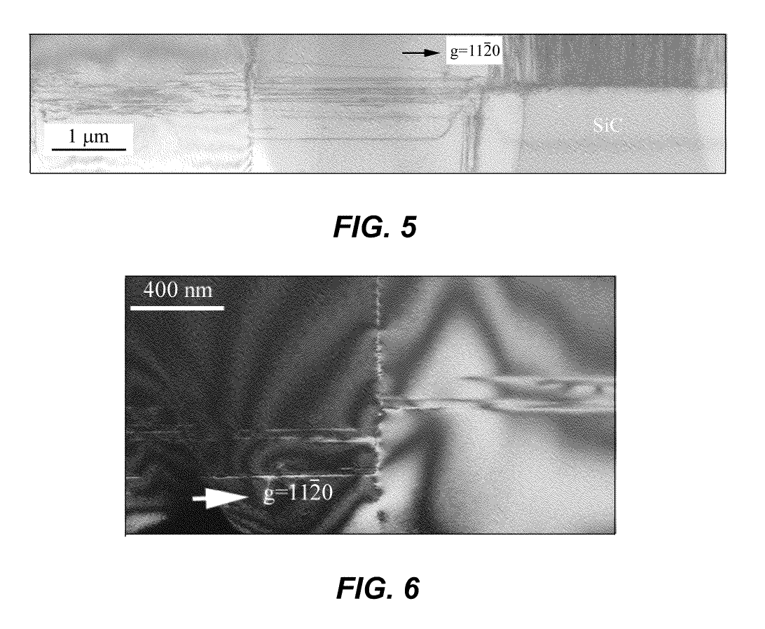

The structural quality and characteristics of the AlN films were assessed by transmission electron microscopy (TEM). TEM analysis indicated that the majority of the observed threading dislocations had pure edge character. FIG. 5 and FIG. 6 are cross-sectional TEM images of AlN films taken under the g=11-20 diffraction conditions to reveal edge character threading dislocations. These images support the conclusions determined from the SEM images that the growth initiates on the SiC substrate posts (generally referred to as the window region or seed region) and then proceeds to grow laterally over the trench region (wing region) until film coalescence occurs. A high concentration of edge-type threading dislocations is observed in the AlN on top of the SiC substrate posts, as can be seen in upper right side of FIG. 5, where the dislocations are the result of lattice mismatch between the AlN film and the substrate. Plan-view TEM revealed a dislocation density of 1-3.5*10⁹ cm⁻² for these regions, which is a typical value for heteroepitaxy of AlN and GaN films on foreign substrates. The present invention has found, however, that the threading dislocations (defects) that nucleate in the Al-containing III-nitride films on top of the posts do not significantly propagate laterally into the wing regions. This enables relatively dislocation free material to be laterally grown over the trench regions using the patterned substrate and elevated growth temperature according to the present invention. Additionally, if and when growth initiates on the sidewalls of the SiC substrate posts, the dislocations that are formed at the interface between the AlN films and the substrate sidewall propagate laterally until they reach laterally growing AlN material from the sidewall of an adjacent post at the coalescence front. These dislocations then generally terminate at the coalescence front, but even more importantly, do not propagate upwards into the growing film, as shown in FIG. 5 and FIG. 6. FIG. 6 shows the termination of these dislocations at the coalescence front, which appears as the vertical line propagating vertically through the center of the TEM image.

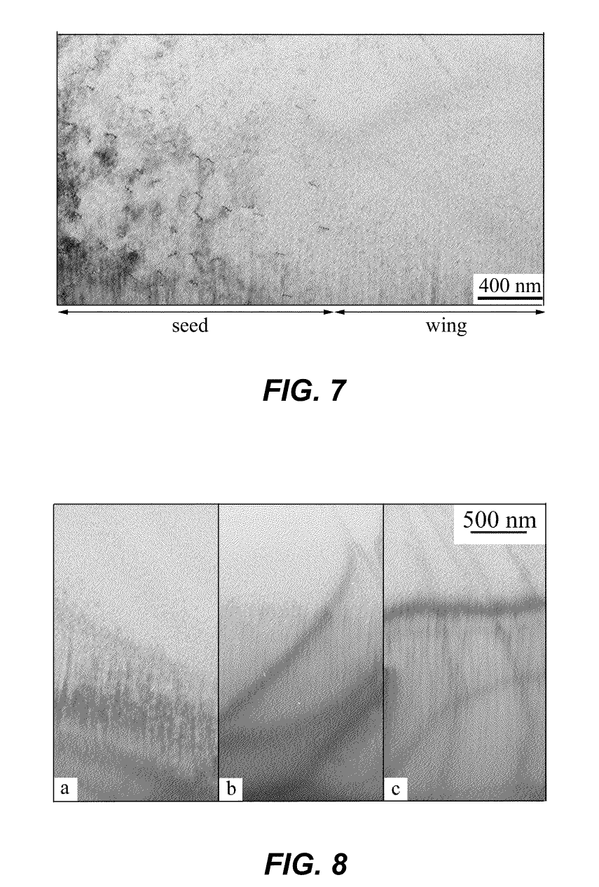

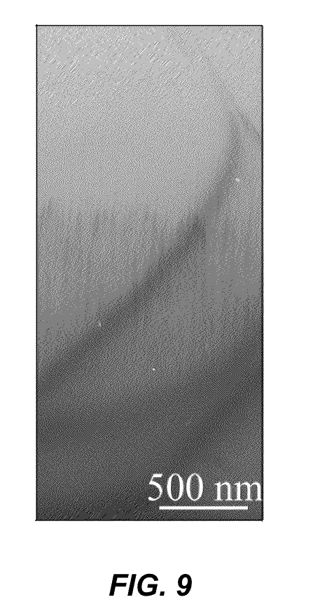

The lateral growth of the AlN and the primarily vertical propagation of the threading dislocations from the seed region enables relatively defect-free material to exist in the AlN between the SiC substrate posts (wing region), as depicted in the TEM image in FIG. 7 with g=11-20 diffraction conditions. Plan-view TEM of three different 4 μm² areas in a wing region of an AlN film revealed no threading dislocations, indicating that the dislocation density in the wing region is below 8.33*10⁶ cm⁻². For the purposes of this invention, however, we will simply assert that the dislocation density is below 10⁷ cm⁻². These three different defect-free areas are shown in the plan view TEM image in FIG. 8, with an enlarged view of one of the defect-free areas appearing in FIG. 9.

To summarize, the laterally grown wing regions of the AlN samples contain very high quality, relatively defect-free material. Further information regarding the laterally grown AlN films can be found in reference [7].

### Manufacture of Free-Standing Films Using Defect Reduction Via Lateral Epitaxial Overgrowth

In another aspect of this invention, a free-standing Al-containing III-nitride semiconductor substrate is produced after growth of the semiconductor film on the patterned substrate described previously. The free-standing layer is produced after cracking occurs in the substrate posts upon cooling due to the coefficient of thermal expansion (CTE) mismatch between the III-nitride semiconductor layer and the substrate. The CTE mismatch between the semiconductor film and the substrate results in stress in both materials upon cooling of the sample from growth temperatures to room temperature. This stress is often relieved by cracking, which according to the present invention, preferentially occurs in at least some, if not all, of the substrate posts during cooling. Cracking of the posts permits relatively easy separation of the Al-containing III-nitride semiconductor film from the substrate, thereby producing a free-standing Al-containing III-nitride semiconductor substrate.

The substrate can be prepared in such manner as to weaken the structural integrity of the posts, and therefore, encourage cracking of the posts during cooling after film growth. These modifications of the posts are still consistent with the defect reduction procedures and Al-containing III-nitride films described previously. There are various different approaches for weakening the posts and these approaches can be used either independently or in combination to achieve the desired effect of weakening the posts so that they crack during cooling. One approach is to reduce the width of the posts. The posts are preferably thinner than 5 μm, and even more preferably thinner than 1 μm. Another approach is to increase the height of the posts. These two approaches are often used in combination to achieve a height-to-width ratio in excess of 1. The higher the value of the height-to-width ratio, the weaker the posts are and the more likely they will fracture upon cooling of the sample. The posts may also be arranged and positioned in such a way that facilitates cracking during cooling or after cooling, such as placing them in a staggered array. Additionally, the posts can be shaped to produce localized weak regions that preferentially crack during cooling, such as “V”-shaped post. In general, forming very thin, tall posts, with large spacing between the posts will encourage cracking of the posts during cooling. The growth of thick layers of Al-containing III-nitride semiconductor films on the patterned substrates will require the relief of stress upon cooling in the form of cracking, and this cracking will typically occur in one or more of the highly stressed substrate posts.

After the substrate is prepared, growth proceeds by the lateral growth and defect reduction method previously discussed as another aspect of this invention. In this aspect of the invention, however, growth is continued after film coalescence to produce thick Al-containing III-nitride semiconductor films on top of the patterned substrate. The growth is continued until the Al-containing III-nitride semiconductor film is preferably thicker than 20 μm, more preferably thicker than 50 μm, more preferably thicker than 100 μm, more preferably thicker than 200 μm, and even more preferably thicker than 300 μm. Increasing the thickness of the Al-containing III-nitride semiconductor film increases the structural integrity and mechanical stability of the layer, which discourages cracking from occurring in the semiconductor film upon cooling, and instead, encourages cracking in the substrate posts. After completion of film growth the substrate is rapidly cooled to facilitate cracking in at least some of the substrate posts due to the coefficient of thermal mismatch between the substrate and Al-containing III-nitride semiconductor film. It is desirable to cool the films as fast as possible to maximize the stress in the substrate posts and promote cracking.

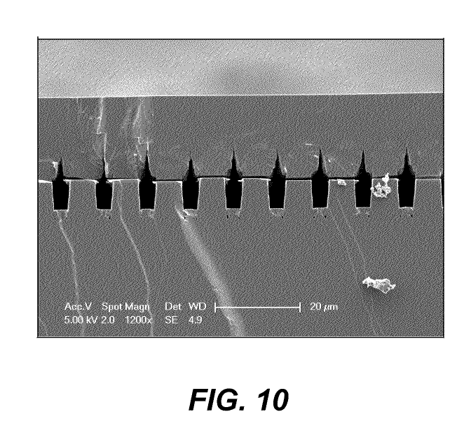

According to this invention, cracking of the substrate posts will typically occur during cool down and release of the Al-containing III-nitride film from the substrate will be relatively easy. FIG. 10 shows an example of the cracking that will occur in the substrate posts according to the present invention. In FIG. 10, horizontal cracking of the SiC substrate posts can be observed due to the CTE mismatch (and the resulting stress) between the SiC and the 15 μm thick AlN layer. If all of the posts do not crack, however, mechanical force or etchants may be utilized to crack the remaining posts. Upon separation of the substrate from the Al-containing III-nitride film, the free-standing Al-containing III-nitride film may then serve as a seed for further epitaxial growth of a III-nitride semiconductor.

The preferred embodiment of the present invention for the growth of high quality, low defect density Al-containing III-nitride semiconductor films includes:
1. Preparation and use of a suitable substrate for Al-containing III-nitride semiconductors that contains elevated regions enabling lateral growth.
2. Use of a growth temperature above 1075° C. for the Al-containing III-nitride semiconductor film growth stage of film deposition.
3. Growth of the Al-containing III-nitride semiconductor film on the prepared substrate where the growth preferentially initiates on the elevated regions of the substrate and proceeds to grow laterally over the lower trench regions to produce a reduced defect density Al-containing III-nitride semiconductor film.

As an example, a c-plane SiC substrate is prepared using conventional photolithography techniques to contain a series of 5 μm-wide nickel (Ni) stripes separated by 5 μm-wide open regions. The Ni stripes function as a mask for the subsequent inductively coupled plasma (ICP) etch. An SF₆ ICP etch is used to etch 10 μm deep trenches in the SiC substrate where the substrate was not covered with Ni. The remaining Ni on the SiC substrate is then etched away using dilute nitric acid and then the wafer is cleaned in acetone, isopropyl alcohol, and deionized water. After drying, the SiC wafer, which now includes a series of 5 μm-wide mesas separated by 5 μm-wide, 10 μm deep trenches, is loaded into the HYPE reactor for growth at temperatures above 1075° C. During the growth process, the AlN film initiates growth on the mesas and proceeds to grow laterally over the trench region. The growth proceeds until the AlN film converges and coalesces with AlN growing laterally from an adjacent stripe.

To form the free-standing layers according to the present invention, growth of the AlN layer continues after coalescence. The film continues to grow vertically until the thickness of the layer is preferably thicker than 20 μm, more preferably thicker than 50 μm, more preferably thicker than 100 μm, more preferably thicker than 200 μm, and even more preferably thicker than 300 μm. Upon completion of growth, the temperature of the sample is rapidly cooled from growth temperature to room temperature as quickly as possible. The cooling time is typically less than 1 hour, but may be greater if rapid cooling is difficult to achieve. The rapid cooling causes extreme stress in the SiC substrate posts on cooling, resulting in cracking of some, if not all, of the substrate posts. The AlN film is then separated from the SiC substrate to form a free-standing AlN layer.

Possible Modifications

There are several possible variations on this technique. The preferred embodiment has described one example of a method for growing reduced dislocation density AlN film via lateral overgrowth on a patterned substrate. Although the growth of AlN was depicted, the present invention is suitable for all Al-containing III-nitride semiconductor films, particularly those films containing high mole fractions of Al. Examples include but are not limited to AlGaN, AlGaInN, AlGaInAsN and AlInN. Additionally, the films may contain other impurities from any group of the periodic table of the elements. For example, doping elements may be incorporated into the growing films, including but not limited to silicon, iron, and magnesium.

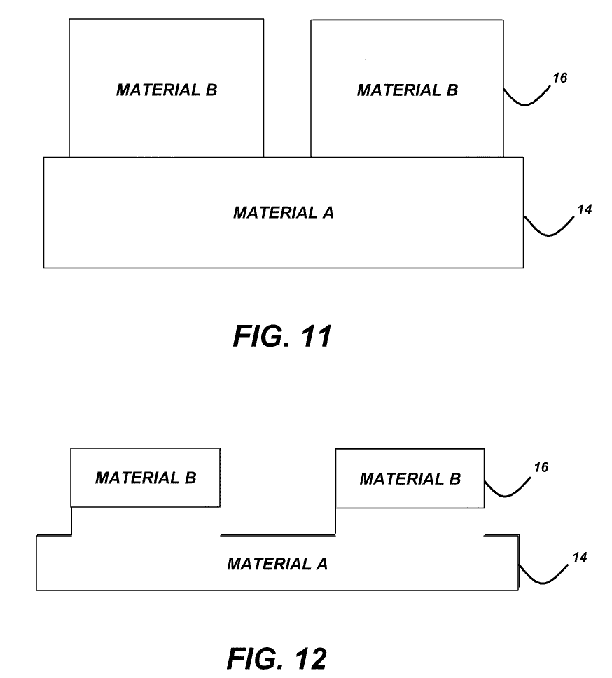

The patterned substrate that is utilized according to the present invention can be made from any materials that can support epitaxial growth of Al-containing III-nitride semiconductor films. Examples of commonly used substrate materials include but are not limited to AlN, GaN, AlGaN, AlGaInN, sapphire (Al₂O₃), silicon carbide (SiC), silicon (Si), ZnO, GaAs, BP, GaP, spinel (MgAl₂O₄), MgO, LiGaO₂, LiAlO₂, NdGaO₃, ScAlMgO₄, Ca₈La₂(PO₄)₆O₂, MoS₂, LaAlO₃, (Mn,Zn)Fe₂O₄, Hf, Zr, ZrN, Sc, ScN, NbN, TiO₂ and TiN. The chosen substrate can then be prepared according to the concepts of the present invention for film growth, and the substrate can be prepared using a variety of different mask materials, mask deposition techniques, etch techniques, and patterning methods without deviating from the concepts of the present invention. Additionally, the substrate could be composed of two or more different materials. An example is growing a thick AlN film on a sapphire substrate and then etching the AlN to prepare the posts and trenches as described in the present invention. In this example the AlN serves as the posts and the trench regions exist over the initial sapphire substrate. A general representation of a substrate prepared according to this method is shown in FIG. 11, wherein the prepared substrate is labeled as comprising the initial substrate Material A 14 and the thick deposited layer Material B 16.

Alternatively, a thin layer of a material 16, labeled as Material B, for example AlN, can be deposited on the initial substrate 14. The thin film 16 may then be selectively etched away and the etch may continue into the initial substrate 14 to form posts that are comprised of the epitaxially deposited film 16 on top of the initial substrate 14, as depicted in FIG. 12. Moreover, any number of materials can be used to compose the posts and trench regions. The present invention requires only that the patterned substrate have one or more elevated regions and be able to support epitaxial growth.

While the present invention has not found the use of nucleation, buffer, or template layers necessary for the successful growth of low defect films, these types of layers may be deposited on any of the previously mentioned substrates before, during or after the etch used to prepare the patterned substrate. The nucleation, buffer, or template layers may also be deposited before or during the growth process by any film growth or deposition technique at any temperature. These layers may subsequently be used for lateral overgrowth according to the present invention.

The present invention has chosen to use elevated stripes for the posts where growth initiates. For demonstration of the present invention, these stripes were oriented in the [symbol] 1-100 [symbol] direction of the growing MN film but could just as easily be oriented along the [symbol] 11-20 [symbol] family of crystallographic direction of the growing film, or even along other directions. While the growth behavior for each orientation differs, it has been shown that the post geometry does not fundamentally alter the practice of this invention. Accordingly, any post geometry can be oriented along any direction according to the present invention.

The present invention has been demonstrated for c-plane Al-containing III-nitride semiconductors. The present invention, however, is equally suitable for other film and substrate orientations, specifically for semipolar and nonpolar orientations.

Although it is typically desirable to continue the lateral growth process until the Al-containing III-nitride films coalesce, coalescence is not a requirement for the present invention. The present inventors have imagined a number of applications where uncoalesced laterally grown films would be desirable. Accordingly, the present invention applies to both coalesced and uncoalesced laterally grown Al-containing III-nitride films. The growth of the films can be halted at any point before, during, or after film coalescence.

Film growth for the present invention was achieved using conventional metal-source hydride vapor phase epitaxy (HVPE). Any derivatives of this technique, however, are still within the scope and spirit of this invention.

The source material used in the source zone may contain Al, a combination of Al with other elements, or any other aluminum containing compound that can be used to form a halogenated product of aluminum. Examples include (but are not limited to):
1. mixed aluminum sources containing Group III sources of B, Ga, In, and/or Tl
2. mixed aluminum-containing sources containing any other element or elements other than aluminum
3. Al-containing adducts such as AlClₓ:(NH)_{y}, and
4. Al-containing compounds that can decompose and/or react to yield a halogenated aluminum product.

The source material can also be pre-reacted metal halide source materials, such as AlCl₃, which can be delivered to the source zone and then heated. Furthermore, our research on the lateral growth of Al-containing III-nitride films has established that simple modifications of the process will allow the technique to be adapted for growth by metalorganic chemical vapor deposition (MOCVD).

Advantages and Improvements

This invention represents the first known lateral overgrowth of AlN by HVPE. This invention also reports the lowest dislocation density for an AlN film grown by a vapor phase epitaxial method with a dislocation density below 10⁷ cm⁻². The reduced defect density films will permit the production of improved electronic and optoelectronic devices that are subsequently grown on the template films and free-standing layers grown by this invention. These high quality Al-containing III-nitride layers may also be used as high-quality seed crystals for subsequent bulk growth.

This invention also permits the fabrication of high quality, reduced defect density, free-standing Al-containing III-nitride semiconductors, particularly AlN and AlGaN. Industry is currently in high demand of these free-standing substrates, which should greatly improve the efficiency and quality of subsequently grown electronic and optoelectronic devices. There are currently few suppliers of free-standing AlN wafers and even fewer suppliers (if any) of transparent AlN wafers, as can be produced according to this invention. Sublimation growth is currently the leader in providing low dislocation density AlN wafers, but the size of the wafers is limited to diameters below 2-inch (typically much less) and the AlN layers are not transparent to ultraviolet (UV) light due to high levels of impurities, effectively making them unsuitable for most UV optoelectronic applications. This invention permits the fabrication of large, transparent AlN and AlGaN wafers.

Method of Fabrication

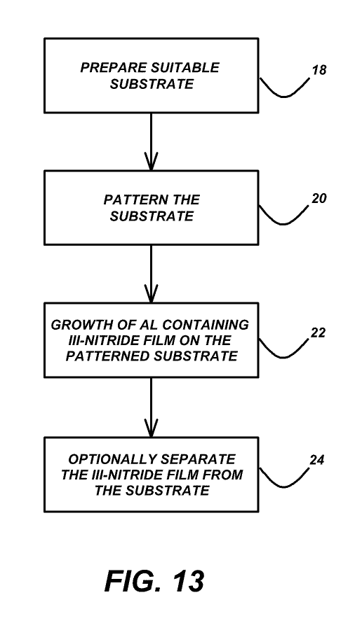

FIG. 13 is a flowchart that illustrates the process steps of the method for the growth of high quality, low defect density Group III-nitride semiconductor films containing aluminum, according to a preferred embodiment of the present invention.

Block 18 represents the step of preparing the substrate. The substrate may comprise AlN, GaN, AlGaN, AlGaInN, sapphire (Al₂O₃), silicon carbide (SiC), silicon (Si), ZnO, GaAs, BP, GaP, spinel (MgAl₂O₄), MgO, LiGaO₂, LiAlO₂, NdGaO₃, ScAlMgO₄, Ca₈La₂(PO₄)₆O₂, MoS₂, LaAlO₃, (Mn,Zn)Fe₂O₄, Hf, Zr, ZrN, Sc, ScN, NbN, TiO₂, aluminum oxide material, TiN, a Group III-V material, or a Group II-VI material. These materials may be used singly or in combination to form the substrate.

Block 20 represents the step of patterning the substrate. Preferably, the substrate is patterned with at least one structure from a group comprising apertures, stripes, arrays, circles, hexagons, or rectangles. The structures may be oriented along a [symbol] 1-100 [symbol] direction or a [symbol] 11-20 [symbol] direction of the substrate or the Group III-nitride film, or along any other direction.

Preferably, the substrate is patterned to contain one or more elevated regions or posts that support epitaxial growth.

Block 22 represents the step of growing the Group III-nitride film containing aluminum on the substrate at a temperature designed to increase the mobility of aluminum atoms to increase a lateral growth rate of the Group III-nitride semiconductor film. In one embodiment, the temperature is preferably greater than 1075° C. In this step, the Group III-nitride semiconductor film may be grown using hydride vapor phase epitaxy (HVPE), or metalorganic chemical vapor deposition (MOCVD), or another similar method.

Preferably, the Group III-nitride film includes at least one of B, Al, Ga, In and Tl. In addition, the Group III-nitride film may be a semipolar or nonpolar Group III-nitride film.

The Group III-nitride film also may contain one or more additional elements including those selected from a group comprising silicon (Si), magnesium (Mg), germanium (Ge), beryllium (Be), calcium (Ca), iron (Fe), carbon (C), cobalt (Co), manganese (Mn) and nickel (Ni).

Note that, in some embodiments, a nucleation, buffer or template layer may be formed on the substrate before, during, or after the patterning step. In addition, in some embodiments, a nucleation, buffer, or template layer may be formed on the Group III-nitride film before or during the growing step.

The growth of the Group III-nitride film initiates on one or more of the elevated post regions and proceeds to grow laterally over one or more of the trench regions, wherein the dislocation density of the Group III-nitride film is reduced in the laterally grown regions. Preferably, the Group III-nitride film has a dislocation density of less than 10⁷ cm⁻². The elevated post regions have a height chosen to allow the Group III-nitride film to coalesce prior to the growth from the bottom of the trench regions reaching the top of the elevated post regions. Preferably, the posts have a height-to-width ratio in excess of 0.5, but this is not required.

Block 24 represents the optional step of separating the resulting Group III-nitride film from the substrate.

For example, when the substrate is patterned with a plurality of posts, the Group III-nitride film may separated from the substrate after cooling the substrate with the Group III-nitride film at a rate that cracks one or more of the posts, such that the Group III-nitride film is separated from the substrate by cracking of all of the posts, by applying an etchant, and/or by applying a mechanical force.

In another example, when the substrate is patterned with a plurality of posts, the Group III-nitride film may be separated from the substrate after cracking one or more of the posts on cooling from an elevated temperature due to the coefficient of thermal expansion mismatch between the Group III-nitride film and the substrate.

Finally, the resulting Group III-nitride film may comprise a seed for additional growth of a Group III-nitride semiconductor layer. Additional layers or device structures may be grown on the resulting Group III-nitride film.

### REFERENCES

The following references are incorporated by reference herein.

1. U.S. Pat. No. 6,599,362, issued Jul. 29, 2003, to Ashby et al., and entitled “Cantilever epitaxial process.”

2. Z. Chen, R. S. Qhalid Fareed, M. Gaevski, V. Adivarahan, J. W. Yang, J. Mei, F. A. Ponce and M. Asif Khan, Appl. Phys. Lett. 89, 081905 (2006).

3. J. Mei, F. A. Ponce, R. S. Qhalid Fareed, J. W. Yang and M. Asif Khan, Appl. Phys. Lett. 90, 221909 (2007).

4. M. Imura, K. Nakano, T. Kitano, N. Fujimoto, G. Narita, N. Okada, K. Balakrishnan, M. Iwaya, S. Kamiyama, H. Amano, I. Akasaki, K. Shimono, T. Noro, T. Takagi and A. Bandoh, Appl. Phys. Lett. 89, 221901 (2006).

5. M. Imura, K. Nakano, G. Narita, N. Fujimoto, N. Okada, K. Balakrishnan, M. Iwaya, S. Kamiyama, H. Amano, I. Akasaki, T. Noro, T. Takagi and A. Bandoh, J. Cryst. Growth 298, 257 (2006).

6. N. Okada, N. Kato, S. Sato, T. Sumi, N. Fujimoto, M. Imura, K. Balakrishnan, M. Iwaya, S. Kamiyama, H. Amano, I. Akasaki, T. Takagi , T. Noro and A. Bandoh, J. Cryst. Growth 300, 141 (2007).

7. D. S. Kamber, S. A. Newman, Y. Wu, E. Letts, S. P. DenBaars, J. S. Speck, and S. Nakamura, Appl. Phys. Lett. 90, 122116 (2007).

8. U.S. Pat. No. 7,195,993, issued Mar. 27, 2007, to Zheleva et al., and entitled “Methods of fabricating gallium nitride semiconductor layers by lateral growth into trenches.”

### SUMMARY

In summary, the present invention describes a Group III-nitride semiconductor film containing aluminum, and a method for growing this film. A film is grown by a method of the present invention by patterning a substrate, and growing the Group III-nitride semiconductor film containing aluminum on the substrate at a temperature designed to increase the mobility of aluminum atoms to increase a lateral growth rate of the Group III-nitride semiconductor film.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method of growing a Group III-nitride film containing aluminum, comprising:
patterning a substrate; and
growing the Group III-nitride film containing aluminum on the patterned substrate at a temperature selected to increase the mobility of aluminum atoms to increase a lateral growth rate of the Group III-nitride film.

2-25. (canceled)

26. The method of claim 1, where the substrate is patterned with at least one structure from a group comprising apertures, stripes, arrays, circles, hexagons or rectangles.

27. The method of claim 26, wherein the structures are oriented along a [symbol] 1-100 [symbol] direction of the substrate or the Group III-nitride film.

28. The method of claim 26, wherein the structures are oriented along a [symbol] 11-20 [symbol] direction of the substrate or the Group III-nitride film.

29. The method of claim 1, wherein the substrate is patterned to contain one or more elevated regions or posts that support epitaxial growth.

30. The method of claim 29, wherein the substrate is patterned to contain two or more of the elevated regions or posts, and at least one trench region between the elevated regions or posts.

31. The method of claim 30, wherein the growth of the Group III-nitride film initiates on one or more of the elevated regions or post, and proceeds to grow laterally over one or more of the trench regions.

32. The method of claim 29, wherein the elevated regions or posts have a height chosen to allow the Group III-nitride film to coalesce prior to growth from a bottom of the trench regions reaching a top of the elevated regions or posts.

33. The method of claim 29, wherein the elevated regions or posts have a height-to-width ratio in excess of 0.5.

34. The method of claim 29, wherein the Group III-nitride film is separated from the substrate after cooling, by cracking one or more of the elevated regions or posts, by applying an etchant, or by applying a mechanical force.

35. The method of claim 1, further comprising separating the Group III-nitride film from the substrate.

36. The method of claim 1, wherein the Group III-nitride film containing aluminum is an aluminum nitride film.

37. The method of claim 1, wherein the Group III-nitride film includes at least one of boron (B), aluminum (Al), gallium (Ga), indium (In), and thallium (Tl).

38. The method of claim 1, wherein the Group III-nitride film contains one or more additional elements, including those selected from a group comprised of silicon, germanium, carbon, magnesium, beryllium, calcium, iron, cobalt, nickel, manganese, phosphorus, antimony, bismuth, and arsenic.

39. The method of claim 1, wherein the Group III-nitride film is a semipolar or nonpolar Group III-nitride film.

40. The method of claim 1, wherein a dislocation density of the Group III-nitride film is reduced in lateral growth regions.

41. The method of claim 1, wherein the Group III-nitride film has a dislocation density of less than 10⁷ cm⁻².

42. The method of claim 1, wherein a nucleation, buffer, or template layer is formed on the substrate before, during, or after the patterning step.

43. The method of claim 1, wherein a nucleation, buffer, or template layer is formed on the Group III-nitride film before or during the growing step.

44. The method of claim 1, wherein the substrate contains one or more materials from the group comprising of AlN, GaN, AlGaN, AlGaInN, sapphire (Al₂O₃), silicon carbide (SiC), silicon (Si), ZnO, GaAs, BP, GaP, spinel (MgAl₂O₄), MgO, LiGaO₂, LiAlO₂, NdGaO₃, ScAlMgO₄, Ca₈La₂(PO₄)₆O₂, MoS₂, LaAlO₃, (Mn,Zn)Fe₂O₄, Hf, Zr, ZrN, Sc, ScN, NbN, TiO₂, aluminum oxide material, TiN, a Group III-V material or a Group II-VI material.

45. The method of claim 1, wherein the Group III nitride film is grown using hydride vapor phase epitaxy (HVPE) or metalorganic chemical vapor deposition (MOCVD).

46. The method of claim 1, further comprising the step of growing one or more additional layers or device structures on the Group III-nitride film.

47. The method of claim 1, wherein the lateral growth rate of the Group III-nitride film is 1 micrometer per hour or greater.

48. The method of claim 1, wherein the temperature is greater than 1075° C.

49. The method of claim 24, wherein the temperature is between 1200° C. and 1800° C.

50. The method of claim 1, wherein the Group III-nitride film containing aluminum is grown with a VIII ratio below 700.

51. The method of claim 50, wherein the Group III-nitride film containing aluminum is grown with a VIII ratio below 350.

52. A film grown using the method of claim 1.

53. A semiconductor device including the film of claim 52.
